(19) United States
(12) Patent Application Publication
(10) Pub. No.: US 2014/0251420 A1
(43) Pub. Date: Sep. 11, 2014

(54) TRANSPARENT CONDUCTIVE OXIDE LAYER WITH LOCALIZED ELECTRIC FIELD DISTRIBUTION AND PHOTOVOLTAIC DEVICE THEREOF

(71) Applicant: TSMC SOLAR LTD., Taichung City (TW)

(72) Inventor: Shih-Wei Chen, Kaohsiung City (TW)

(73) Assignee: TSMC SOLAR LTD., Taichung City (TW)

(21) Appl. No.: 13/792,702

(22) Filed: Mar. 11, 2013

(51) Int. Cl. H01L 31/0224; H01L 31/18

(52) U.S. Cl. CPC H01L 31/022466; H01L 31/1884; B82Y 99/00
USPC 136/256; 438/71; 977/948; 977/842

(57) ABSTRACT

A photovoltaic device includes a substrate; a back contact layer disposed above the substrate; an absorber layer for photon absorption disposed above the back contact layer; a buffer layer disposed above the absorber layer; a conductive coating disposed above the buffer layer; and a transparent conductive layer disposed over the conductive coating. The conductive coating includes at least one type of nanomaterial, which has at least one dimension in the range of from 0.5 nm to 1000 nm.

### FIELD

The disclosure relates to photovoltaic devices generally, and more particularly relates to photovoltaic device comprising a transparent conductive layer and the fabrication process of making the same.

### BACKGROUND

Photovoltaic devices (also referred to as solar cells) absorb sun light and convert light energy into electricity. Photovoltaic devices and manufacturing methods therefor are continually evolving to provide higher conversion efficiency with thinner designs.

Thin film solar cells are based on one or more layers of thin films of photovoltaic materials deposited on a substrate. The film thickness of the photovoltaic materials ranges from several nanometers to tens of micrometers. Examples of such photovoltaic materials include cadmium telluride (CdTe), copper indium gallium selenide (CIGS) and amorphous silicon (α-Si). These materials function as light absorbers. A photovoltaic device can further comprise other thin films such as a buffer layer, a back contact layer, and a front contact layer.

### BRIEF DESCRIPTION OF THE DRAWINGS

The present disclosure is best understood from the following detailed description when read in conjunction with the accompanying drawings. It is emphasized that, according to common practice, the various features of the drawings are not necessarily to scale. On the contrary, the dimensions of the various features are arbitrarily expanded or reduced for clarity. Like reference numerals denote like features throughout specification and drawings.

FIGS. 1A-1E are cross-sectional views of a portion of an exemplary photovoltaic device during fabrication, in accordance with some embodiments.

FIG. 2 is a flow chart diagram illustrating a method of fabricating an exemplary photovoltaic device in accordance with some embodiments.

FIG. 3A is a cross-sectional view of a portion of a photovoltaic device during fabrication illustrating an exemplary buffer layer having a textured surface in accordance with some embodiments.

FIG. 3B is a top plan view of a portion of a photovoltaic device during fabrication illustrating a conductive coating deposited on a textured surface of a buffer layer in accordance with some embodiments.

FIG. 4 is a cross-sectional view of a portion of an exemplary photovoltaic device during fabrication in which the absorber layer has a textured surface in accordance with some embodiments.

FIG. 5 is a cross-sectional view of a portion of an exemplary photovoltaic device having scribe lines in accordance with some embodiments.

FIG. 6 is a cross-sectional view of a portion of an exemplary photovoltaic device illustrating that the nanomaterial in a conductive coating having an orientation substantially normal to a scribe line in accordance with some embodiments.

FIG. 7 a top-down view of an exemplary configuration that the nanomaterial in a conductive coating having an orientation substantially normal to a scribe line in a photovoltaic device in accordance with some embodiments.

FIGS. 8A-8E are schematic diagrams illustrating an exemplary process of depositing a conductive coating above the buffer layer in accordance with some embodiments.

FIGS. 9A-9B are schematic diagrams illustrating an exemplary mechanism of forming a conductive coating of nanomaterial having an orientation in accordance with some embodiments. FIG. 9B is an enlarged detail of a portion of FIG. 9A.

FIG. 10 is a schematic diagram illustrating an exemplary process of depositing a conductive coating in a solution comprising carbon nanotubes (CNT) in an electric field in accordance with some embodiments.

### DETAILED DESCRIPTION

This description of the exemplary embodiments is intended to be read in connection with the accompanying drawings, which are to be considered part of the entire written description. In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

A transparent conductive layer is used in a photovoltaic (PV) device with dual functions: transmitting light to an absorber layer while also serving as a front contact to transport photo-generated electrical charges away to form output current. Transparent conductive oxides (TCOs) are used as front contacts in some embodiments. To improve both electrical conductivity and optical transmittance of the transparent conductive layer having TCO are desirable to improve photovoltaic efficiency.

This disclosure provides a photovoltaic device and the method for making the same. In such a photovoltaic device, a conductive coating is used in combination with a transparent conductive layer to improve both electrical conductivity and optical transmittance of the transparent conductive layer. Thus the resulting photovoltaic device has excellent photovoltaic efficiency.

Unless expressly indicated otherwise, references to “nanomaterial” made in this disclosure will be understood to encompass a material having at least one dimension such as diameter and/or length in the range of 0.1 nanometer (nm) to 1000 nm. Examples of a suitable material include but are not limited to nanoparticles, nanotube, nanofiber, nanorod, nanoplatelete, nanosheet and combinations thereof.

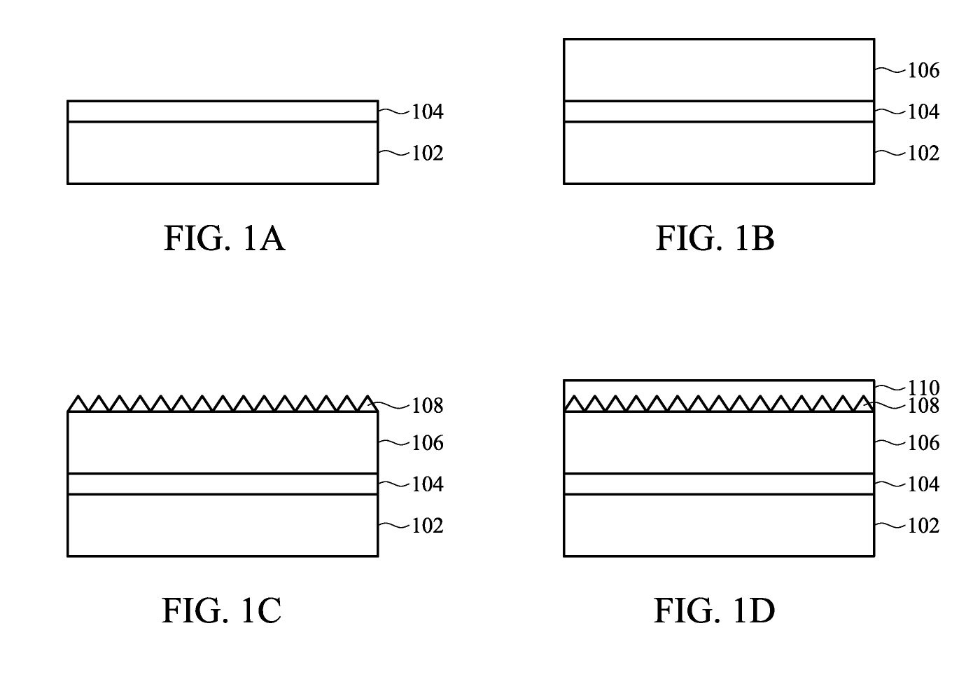

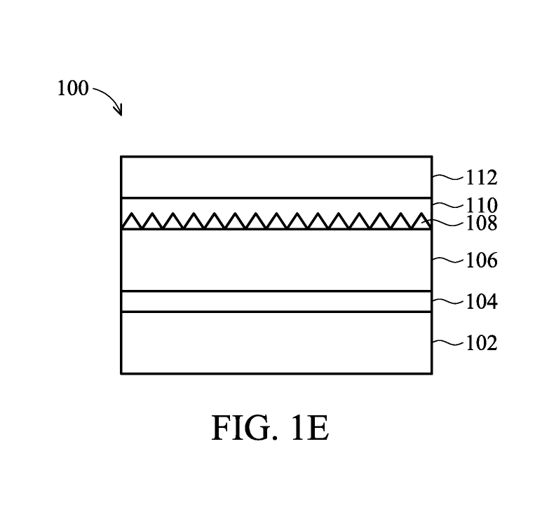

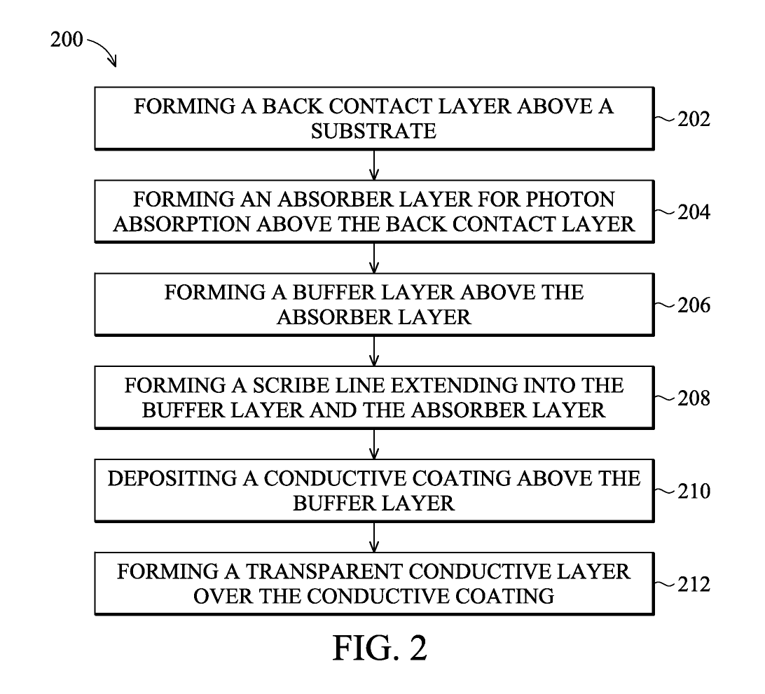

In FIGS. 1A-1E, 3A-3B, 4-7, 8A-10, like items are indicated by like reference numerals, and for brevity, descriptions of the structure, provided above with reference to the previous figures, are not repeated. The methods described in FIG. 2 are described with reference to the exemplary structures described in FIGS. 1A-1E.

FIG. 2 is a flow chart diagram illustrating a method 200 of fabricating an exemplary photovoltaic device in accordance with some embodiments. FIGS. 1A-1E are cross-sectional views of a portion of an exemplary photovoltaic device 100 during fabrication, in accordance with some embodiments.

At step 202, a back contact layer 104 is formed above a substrate 102. The resulting structure of a portion of a photovoltaic device 100 after step 202 is illustrated in FIG. 1A. Substrate 102 and back contact layer 104 are made of any material suitable for thin film photovoltaic devices. Examples of materials suitable for use in substrate 102 include but are not limited to glass (such as soda lime glass), polymer (e.g., polyimide) film and metal foils (such as stainless steel). The film thickness of substrate 102 is in any suitable range, for example, in the range of 0.1 mm to 5 mm in some embodiments. Examples of suitable materials for back contact layer 104 include, but are not limited to copper, nickel, molybdenum (Mo), or any other metals or conductive material. Back contact layer 104 can be selected based on the type of thin film photovoltaic device. For example, in a CIGS thin film photovoltaic device, back contact layer 104 is Mo in some embodiments. In a CdTe thin film photovoltaic device, back contact layer 104 is copper or nickel in some embodiments. The thickness of back contact layer 104 is on the order of nanometers or micrometers, for example, in the range from 100 nm to 20 microns. The thickness of back contact layer 104 is in the range of from 200 nm to 10 microns in some embodiments. Back contact layer 104 can be also etched to form a pattern after step 202.

At step 204, an absorber layer 106 for photon absorption is formed above back contact layer 104. The resulting structure of a portion of the photovoltaic device 100 during fabrication after step 204 is illustrated in FIG. 1B.

Absorber layer 106 is a p-type or n-type semiconductor material. Examples of materials suitable for absorber layer 106 include but are not limited to cadmium telluride (CdTe), copper indium gallium selenide (CIGS) and amorphous silicon (α-Si). In some embodiments, absorber layer 106 is a semiconductor comprising copper, indium, gallium and selenium, such as CuInₓGa₍₁₋ₓ₎Se₂, where x is in the range of from 0 to 1. In some embodiments, absorber layer 106 is a p-type semiconductor comprising copper, indium, gallium and selenium. Absorber layer 106 has a thickness on the order of nanometers or micrometers, for example, 0.5 microns to 10 microns. In some embodiments, the thickness of absorber layer 106 is in the range of 500 nm to 2 microns.

Absorber layer 106 can be formed according to methods such as sputtering, chemical vapor deposition, printing, electrodeposition or the like. For example, CIGS is formed by first sputtering a metal film comprising copper, indium and gallium at a specific ratio, followed by a selenization process of introducing selenium or selenium containing chemicals in gas state into the metal firm. In some embodiments, the selenium is deposited by evaporation physical vapor deposition (PVD).

At step 206, a buffer layer 108 is formed above absorber layer 106. The resulting structure of a portion of the photovoltaic device 100 during fabrication after step 206 is illustrated in FIG. 1C. Examples of buffer layer 108 include but are not limited to CdS or ZnS, in accordance with some embodiments. The thickness of buffer layer 108 is on the order of nanometers, for example, in the range of from 5 nm to 100 nm in some embodiments.

Formation of buffer layer 108 is achieved through a suitable process such as sputtering or chemical vapor deposition. For example, in some embodiments, buffer layer 108 is a layer of CdS, ZnS or a mixture of CdS and ZnO, deposited through a hydrothermal reaction or chemical bath deposition (CBD) in a solution. For example, in some embodiments, a buffer layer 108 comprising a thin film of ZnS is formed above absorber layer 106 comprising CIGS. The buffer layer 108 is formed in an aqueous solution comprising ZnSO₄, ammonia and thiourea at 80° C. A suitable solution comprises 0.16M of ZnSO₄, 7.5M of ammonia, and 0.6 M of thiourea in some embodiments.

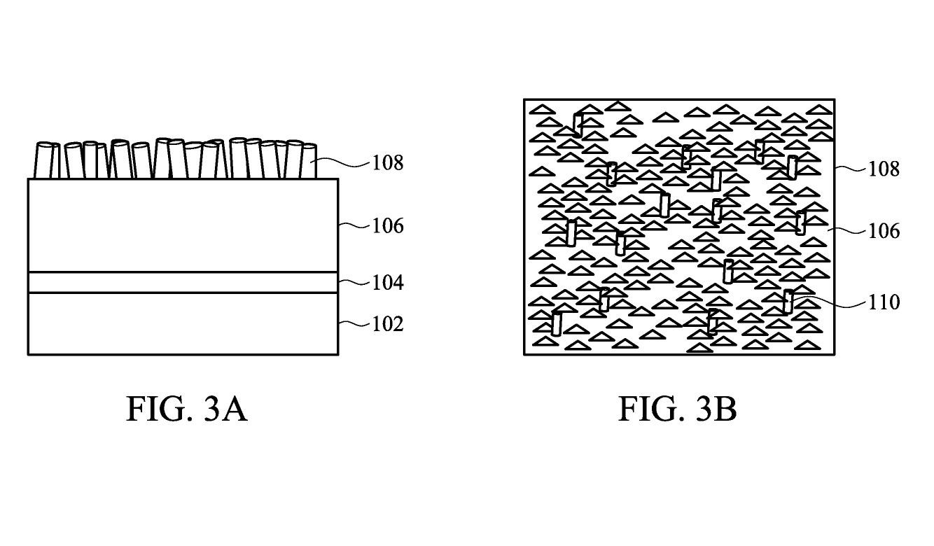

Either buffer layer 108 or absorber layer 106 has a textured surface in some embodiments. In some embodiments, buffer layer 108 has a textured surface, as shown in FIG, 1C. Such a textured surface can be formed through etching, or in-situ deposition of a material comprising nanotubes, nanorods or nanotips. For example, the textured or rough surface of buffer layer 108 can be formed of nanotubes vertically grown on the surface of absorbed layer 106. The resulting structure is illustrated in FIG. 3A. For example, such buffer layer 108 can comprise intrinsic ZnO nanotubes prepared through through a hydrothermal reaction or chemical bath deposition in a solution. The solution comprises a zinc-containing salt and an alkaline chemical. Any zinc containing salt can be zinc nitrate, zinc acetate, zinc chloride, zinc sulfate, combinations and hydrates thereof. One example of hydrate is zinc nitrate hexahydrate, zinc nitrate or zinc acetate. The alkaline chemical in the solution can be a strong base such as KOH or NaOH or a weak base such as ammonia or an amine.

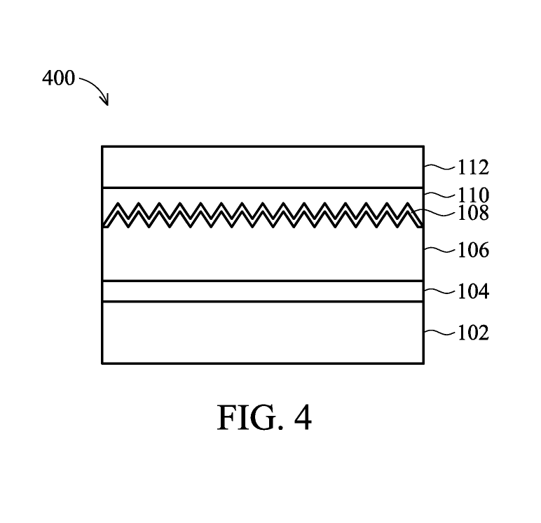

In some embodiments, absorber layer 106 has a textured surface. Both absorbed layer 106 and buffer layer 108 have a textured surface in some embodiments. An exemplary device 400 is illustrated in FIG. 4. Such a textured surface can be formed through etching, or in-situ deposition of a suitable material having structure of nanotubes, nanorods or nanotips. As one example, a buffer layer 108 comprising CdS or ZnS and having a textured surface can be made by using metal organic chemical vapor deposition (MOCVD).

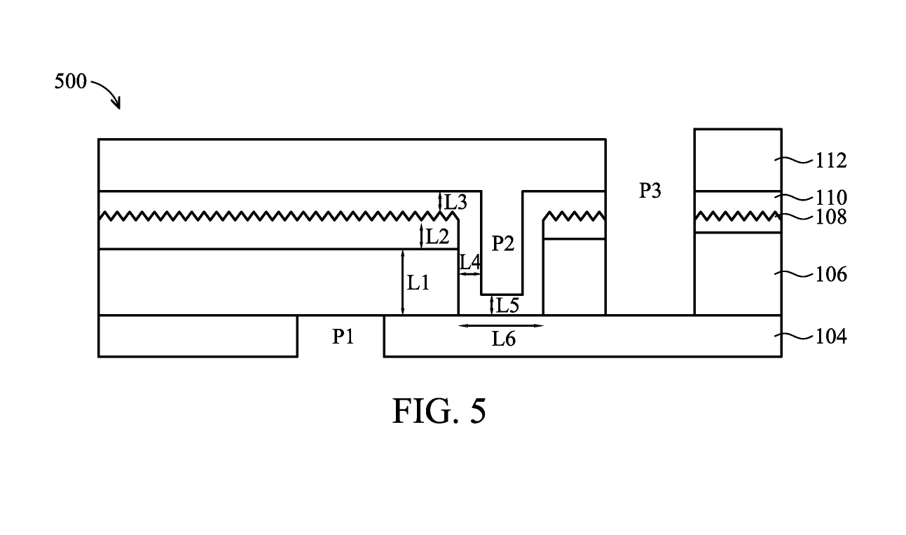

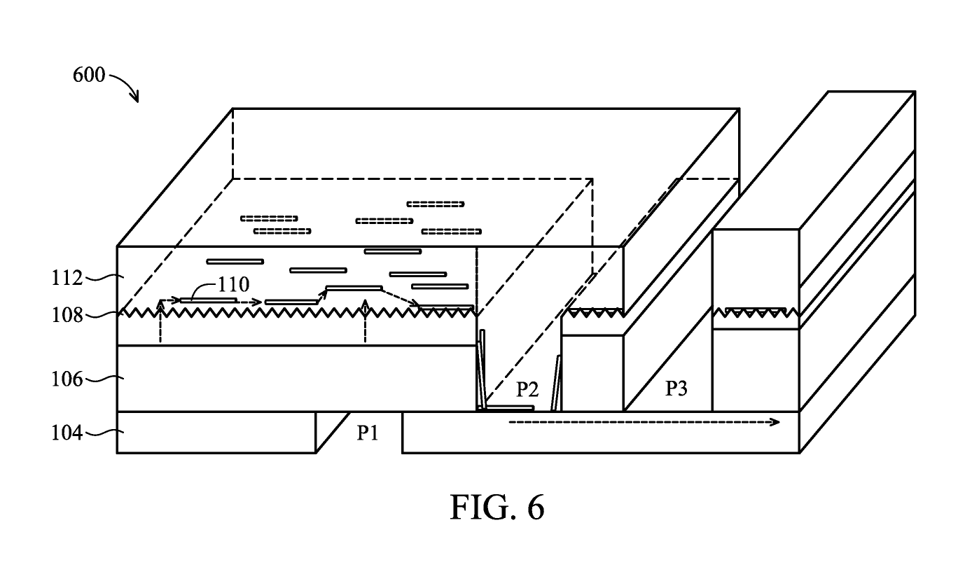

In some embodiments, method 200 also comprises forming a scribe line extending into buffer layer 108 and absorber layer 106. Step 208 of FIG. 2 is an optional step in some embodiments. At step 208, a scribe line extending into buffer layer 108 and absorber layer 106 is formed through a suitable method, for example a laser scribing or mechanical scribing process. For example, an exemplary PV device 500 or 600 having such a scribe line (P2) is illustrated in FIGS. 5 and 6, respectively.

Referring back to FIG. 2, at step 210, a conductive coating 110 comprising at least one type of nanomaterial having at least one dimension in the range of from 0.5 nm to 1000 nm is deposited above buffer layer 108. The resulting structure of a portion of the photovoltaic device 100 during fabrication after step 210 is illustrated in FIG. 1D. The thickness of conductive coating 110 is in the order of nanometers or microns, for example in the range of from 0.5 nm to 500 nm in some embodiments.

Conductive coating 110 comprises at least one type of nanomaterial having at least one dimension such as particle size, diameter or length in the range of from 0.5 nm to 1000 nm. The nanomaterial for conductive coating 110 can be in a form such as nanotube, nanoplatelet, nanorod, nanoparticle, nanosheet or any other shapes or combinations thereof. The nanomaterial for conductive coating 110 can be made of carbon, graphite, metal or any other inorganic or organic conductive materials. Examples of suitable materials for conductive coating 110 include but are not limited to carbon nanotubes, graphene nanoplatelets or nanosheet, metal nanotubes, metal nanorods, and metal nanoparticles. In some embodiments, the nanomaterial in conductive coating 110 comprises graphene nanoplatelets, carbon nanotubes (CNT) or silver nanoparticles. The nanomaterial in conductive coating 110 comprises carbon nanotubes in some embodiments. Examples of suitable carbon nanotubes (CNT) include but are not limited to single wall CNT, double wall CNT, and multiple wall CNT.

Depositing conductive coating 110 can be achieved through a suitable process such as dip coating, spin coating, spray coating, in-situ deposition of conductive coating 110, or any other suitable method. In some embodiments, conductive coating 110 is formed by depositing the nanomaterial dispersed in a solution. For example, depositing conductive coating 110 above the buffer layer 108 is performed in a solution comprising carbon nanotubes (CNT) in an electric field. The conductive coating over the buffer layer 108 comprises carbon nanotubes having a specific orientation, for example, in an orientation substantially normal to the scribe line in some embodiments. FIG. 3B is a top-down view of a portion of an exemplary photovoltaic device during fabrication illustrating a conductive coating 110 deposited on a textured surface of a buffer layer 108 in accordance with some embodiments. As illustrated in FIG. 3B, some portion of absorber layer 106 can be seen on the textured surface of the buffer layer 108.

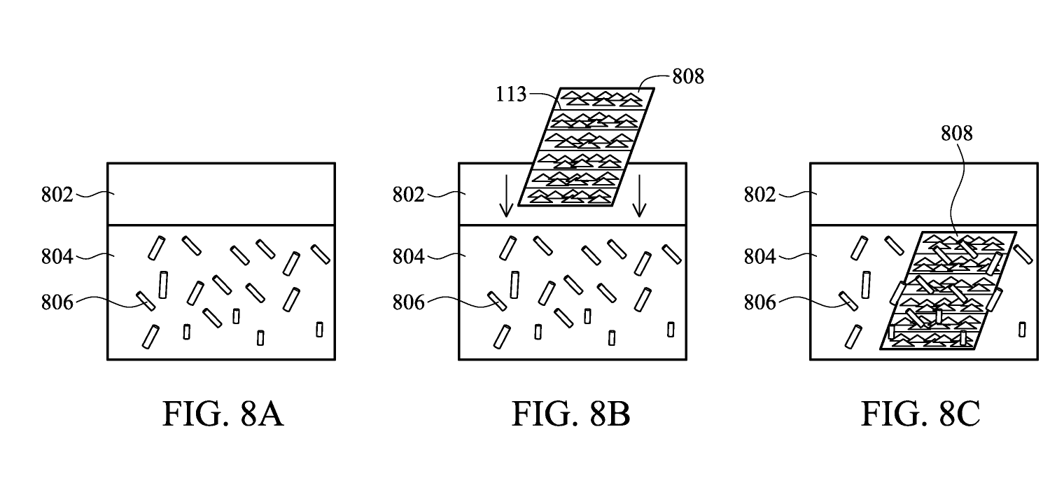

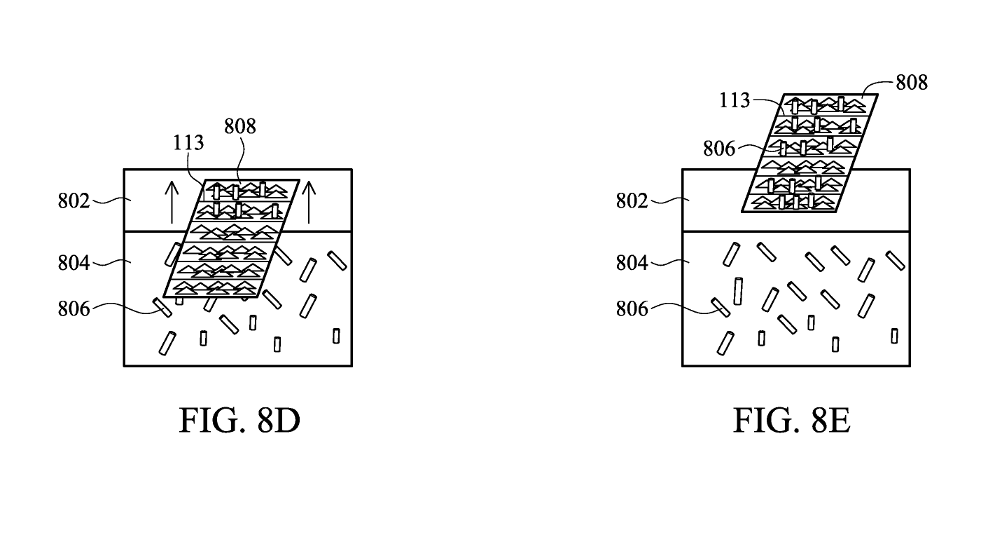

FIGS. 8A-8E are schematic diagrams illustrating an exemplary process of depositing a conductive coating 110 above the buffer layer 108 in accordance with some embodiments. Referring to FIG. 8A, a solution 801 in a container 802 comprises dispersion of nanomaterial 806 for conductive coating 110. As described with respect to FIG. 1D, the nanomaterial 806 can be in a form such as nanotube, nanoplatelet, nanorod, nanoparticle, nanosheet or any other shapes or combinations thereof. The nanomaterial for conductive coating 110 can be made of carbon, graphite, metal or any other inorganic or organic conductive materials. In some embodiments, the nanomaterial 806 in conductive coating 110 comprises graphene nanoplatelets, carbon nanotubes (CNT) or silver nanoparticles. The nanomaterial 806 comprises carbon nanotube (CNT) in some embodiments. The suitable CNT can be single wall CNT, double wall CNT, multiple wall CNT, or any combination thereof. Carbon nanotubes used are purified before dispersion in some embodiments. Carbon nanotubes can be dispersed in an aqueous solution comprising dispersant such as a surfactant. For example, CNTs are dispersed in deionized water using a surfactant. Examples of a suitable surfactants include but are not limited to butoxyethanol, tetramethyl-5-decyne-4,7-diol, and alpha-(nonylphenyl)-omega-hydroxy-poly(oxy-1,2-ethanediyl).

Referring to FIG. 8B, an exemplary photovoltaic device 808 being fabricated is dipped into the solution 804 comprising dispersions of nanomaterial 806. As described in FIG. 1C, the exemplary photovoltaic device 808 comprises a buffer layer 108 and an absorber layer 106. Either buffer layer 108 or absorber layer 106 has a textured surface.

Referring to FIG. 8C, exemplary photovoltaic device 808 is immersed into solution 804. Dispersions of nanomaterial 806 are deposited onto a textured surface of buffer layer 108. FIG. 8D illustrates the process of pulling photovoltaic device 808 out of the solution vertically. In some embodiments, photovoltaic device 808 comprises at least one scribe line 113 as described with respect to FIGS. 5-6. For example, a scribe line extending into absorber layer 106 and buffer layer 108 is marked as “P2” in FIGS. 5-6. The pulling direction is also normal to the at least one scribe line 113.

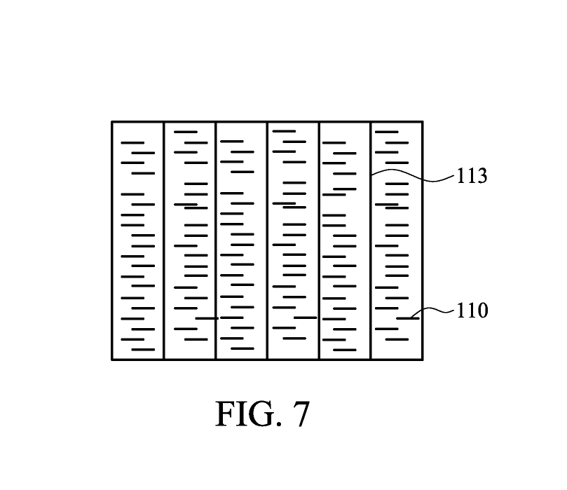

Referring to FIG. 8E, after exemplary photovoltaic device 808 is completely out of the solution 804, dispersions of nanomaterial 806 are aligned in a direction parallel to the pulling direction and normal to the scribe line 113. Such coating of nanomaterial 806 is conductive coating 110. Conductive coating 110 having such an orientation of nanomaterial 806 are also illustrated in FIG. 3B and FIG. 7.

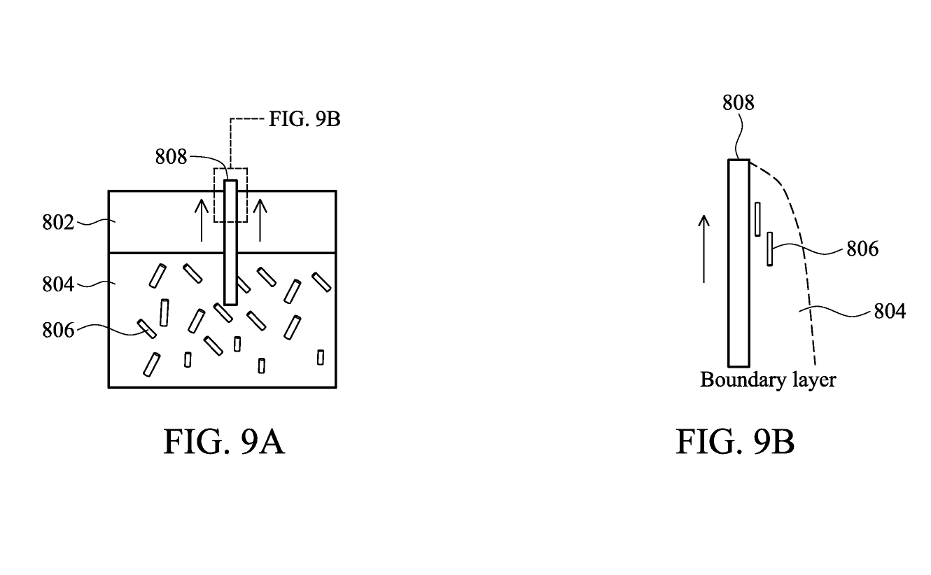

FIGS. 9A-9B are schematic diagrams illustrating an exemplary mechanism of forming a conductive coating 110 of nanomaterial having an orientation in accordance with some embodiments. FIG. 9B is an enlarged detail of a portion of FIG. 9A. As described in FIG. 8D, the exemplary photovoltaic device 808 during fabrication is pulled out vertically out of solution 804 comprising nanomaterials 806 for conductive coating 110 (FIG. 9A). A boundary layer of solution 804 comprising nanomaterial 806 is formed on the surface of exemplary photovoltaic device 808. In this boundary layer, dispersion of nanomaterial 806 are oriented parallel to the pulling direction. After drying, a conductive coating 110 can be formed with a specific orientation of nanomaterial 806 such as carbon nanotubes in some embodiments.

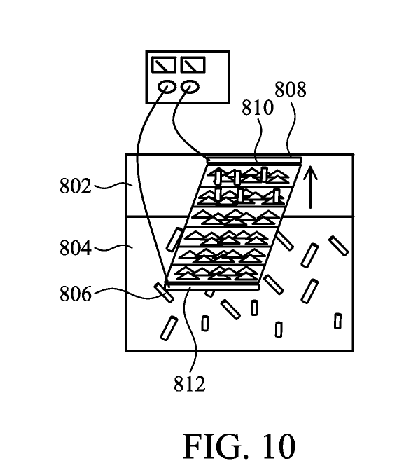

The process of forming such an orientation of nanomaterial 806 can be assisted through using an electric or magnetic field in some embodiments. FIG. 10 is a schematic diagram illustrating an exemplary process of depositing a conductive coating 110 in a solution comprising carbon nanotubes (CNT) in an electric field in accordance with some embodiments. In FIG. 10, like items are indicated by like reference numerals, and for brevity, descriptions of the structure, provided above with reference to FIG. 8A-8E, are not repeated. As shown in FIG. 10, two ends of exemplary photovoltaic device 808 being fabricated are connected with two electrodes 810 and 812. A voltage or current is applied onto photovoltaic device 808 through a source 814. The electric current is alternating current (AC) with a voltage in the range from 0.1 volt to 30 volts in some embodiments, or is direct current (DC) with a voltage in the range from 0.1 volt to 100 volts in some other embodiments.

In an exemplary solution comprising CNT, the weight ratio of CNT to a solvent can be in the range of 10⁻⁴ to 10⁻². Suitable CNTs can be single wall CNT, with a diameter in the range of from 0.8 to 2 nm and a length in the range of from 5 μm to 30 μm. Suitable CNTs can be multiple wall CNT, with a diameter in the range of from 3 to 50 nm and a length in the range of from 10 μm to 50 μm.

Referring back to FIG. 2, at step 212, a transparent conductive layer 112 is formed over conductive coating 110. The resulting structure of a portion of the photovoltaic device 100 during fabrication after step 212 is illustrated in FIG. 1E. Examples of a suitable material for transparent conductive layer 112 include but are not limited to transparent conductive oxides such as indium tin oxide (ITO), fluorine-doped tin oxide (FTO), aluminum-doped zinc oxide (AZO), gallium doped ZnO (GZO), alumina and gallium co-doped ZnO (AGZO), boron doped ZnO (BZO), and any combination thereof. A suitable material for transparent conductive layer 112 can also be a composite material comprising at least one of the transparent conductive oxide (TCO) and another conductive material, which does not significantly decrease electrical conductivity or optical transparency of transparent conductive layer 112. The thickness of transparent conductive layer 112 is in the order of nanometers or microns, for example in the range of from 0.3 nm to 2.5 μm in some embodiments.

As described above, in one aspect, the present disclosure provides a photovoltaic device. FIGS. 1E, 4 and 5-6 illustrate examples of a photovoltaic device in accordance with some embodiments. As shown in FIG. 1E and 4, in some embodiments, a photovoltaic device 100 or 400 comprises a substrate 102; a back contact layer 104 disposed above substrate 102; an absorber layer 106 for photon absorption disposed above back contact layer 104; a buffer layer 108 disposed above absorber layer 106; a conductive coating 110 disposed above buffer layer 108; and a transparent conductive layer 112 disposed over conductive coating 110. Both absorber layer 106 and buffer layer 108 are semiconductors. Conductive coating 110 comprises at least one type of nanomaterial having at least one dimension in the range of from 0.5 nm to 1000 nm. In some embodiments, either buffer layer 108 or absorber layer 106 has a textured surface. As shown in FIG. 1E, buffer layer 108 has a textured surface in some embodiments. As shown in FIG. 4, absorber layer 106, or both buffer layer 108 and absorber layer 104 have a textured surface.

In some embodiments, transparent conductive layer 112 comprises a transparent conductive oxide (TCO). In some embodiments, conductive coating 110 has a thickness in the range of from 0.5 nm to 500 nm. In some embodiments, the conductive coating comprises graphene nanoplatelets. In some embodiments, conductive coating 110 comprises silver nanoparticles. In some embodiments, conductive coating 110 comprises carbon nanotubes (CNT).

In some embodiments, as shown in FIGS. 5-6, photovoltaic device 500 or 600 further comprises a scribe line (e.g., P2) extending into buffer layer 108 and absorber layer 106. FIG. 5 is a cross-sectional view of a portion of an exemplary photovoltaic device 500 having scribe lines (P1, P2 and P3) in accordance with some embodiments. The width of the scribe line P2 is in the range of 1-100 microns, for example, 40 microns in some embodiments. The thickness of absorber layer 106 (L1) and buffer layer 108 (L2) are in the range of from 500 nm to 2 microns, and from 5 nm to 500 nm, respectively. The thickness of conductive coating 110 above buffer layer 108 (L3), or in the scribe line P2 (L4, or L5) are in the range of from 0.5 nm to 500 nm, for example, in the range of from 10 nm to 400 nm in some embodiments. P1 is formed through patterning back contact layer 104 and filling with absorber layer 106.

The nanomaterials such as carbon nanotubes in conductive coating 110 over buffer layer 108 have an orientation substantially normal to the scribe lines such as P2 (or scribe line 113 in FIG. 7) in some embodiments. FIG. 6 is a cross-sectional view of a portion of an exemplary photovoltaic device 600 illustrating that the nanomaterial in a conductive coating 110 having an orientation substantially normal to a scribe line P2 in accordance with some embodiments. As shown in FIG. 6, in some embodiments, conductive coating 110 is a non-continuous coating having some spaces or a plurality of voids among the carbon nanotubes. Transparent conductive layer 112 fills the space or the plurality of voids among the carbon nanotubes.

The present disclosure provides a photovoltaic device and a method of fabricating such a photovoltaic device. In accordance with some embodiments, a photovoltaic device comprises a substrate; a back contact layer disposed above the substrate; an absorber layer for photon absorption disposed above the back contact layer; a buffer layer disposed above the absorber layer; a conductive coating disposed above the buffer layer; and a transparent conductive layer disposed over the conductive coating. The conductive coating comprises at least one type of nanomaterial having at least one dimension in the range of from 0.5 nm to 1000 nm. In some embodiments, either the buffer layer or the absorber layer has a textured surface. In some embodiments, the transparent conductive layer comprises a transparent conductive oxide (TCO). In some embodiments, the conductive coating has a thickness in the range of from 0.5 nm to 500 nm. In some embodiments, the conductive coating comprises graphene nanoplatelets. In some embodiments, the conductive coating comprises silver nanoparticles. In some embodiments, the conductive coating comprises carbon nanotubes (CNT). In some embodiments, the photovoltaic device further comprises a scribe line extending into the buffer layer and the absorber layer. The carbon nanotubes in the conductive coating over the buffer layer have an orientation substantially normal to the scribe line. In some embodiments, the conductive coating is a non-continuous coating having a plurality of voids among the carbon nanotubes. The transparent conductive layer fills the plurality of voids among the carbon nanotubes.

In accordance with some embodiments, a photovoltaic device comprises a substrate; a back contact layer disposed above the substrate; an absorber layer disposed above the back contact layer; a buffer layer disposed above the absorber layer, wherein both the absorber layer and the buffer layer are semiconductors; a conductive coating comprising carbon nanotubes or graphene nanoplatelets disposed above the buffer layer; and a transparent conductive oxide (TCO) layer disposed over the conductive coating. In some embodiments, the conductive coating has a thickness in the range of from 0.5 nm to 500 nm. In some embodiments, either the absorber layer or the buffer layer has a textured surface. In some embodiments, the conductive coating comprises carbon nanotubes (CNT). In some embodiments, the photovoltaic device comprises a scribe line extending into the buffer layer and the absorber layer. The carbon nanotubes in the conductive coating over the buffer layer have an orientation substantially normal to the scribe line.

The present disclosure also provides a method of fabricating a photovoltaic device. The method comprises the steps of: forming a back contact layer above a substrate; forming an absorber layer for photon absorption above the back contact layer; forming a buffer layer above the absorber layer; depositing a conductive coating above the buffer layer; and forming a transparent conductive layer over the conductive coating. The conductive coating comprises at least one type of nanomaterial having at least one dimension in the range of from 0.5 nm to 1000 nm. In some embodiments, either the buffer layer or the absorber layer has a textured surface. In some embodiments, the nanomaterial in the conductive coating comprises graphene nanoplatelets, carbon nanotubes (CNT) or silver nanoparticles. In some embodiments, the conductive coating is formed by depositing the nanomaterial dispersed in a solution.

In some embodiments, the method further comprises forming a scribe line extending into the buffer layer and the absorber layer. In some embodiments, depositing the conductive coating above the buffer layer is performed in a solution comprising carbon nanotubes (CNT) in an electric field. The conductive coating over the buffer layer comprises carbon nanotubes having an orientation substantially normal to the scribe line.

Although the subject matter has been described in terms of exemplary embodiments, it is not limited thereto. Rather, the appended claims should be construed broadly, to include other variants and embodiments, which may be made by those skilled in the art.

What is claimed is:

1. A photovoltaic device comprising:
a substrate;
a back contact layer disposed above the substrate;
an absorber layer for photon absorption disposed above the back contact layer;
a buffer layer disposed above the absorber layer;
a conductive coating disposed above the buffer layer; and
a transparent conductive layer disposed over the conductive coating,
wherein the conductive coating comprises at least one type of nanomaterial having at least one dimension in the range of from 0.5 nm to 1000 nm.

2. The photovoltaic device of claim 1, wherein either the buffer layer or the absorber layer has a textured surface.

3. The photovoltaic device of claim 1, wherein the transparent conductive layer comprises a transparent conductive oxide (TCO).

4. The photovoltaic device of claim 1, wherein the conductive coating has a thickness in the range of from 0.5 nm to 500 nm.

5. The photovoltaic device of claim 1, wherein the conductive coating comprises graphene nanoplatelets.

6. The photovoltaic device of claim 1, wherein the conductive coating comprises silver nanoparticles.

7. The photovoltaic device of claim 1, wherein the conductive coating comprises carbon nanotubes (CNT).

8. The photovoltaic device of claim 7, further comprising:
a scribe line extending into the buffer layer and the absorber layer,
wherein the carbon nanotubes in the conductive coating over the buffer layer have an orientation substantially normal to the scribe line.

9. The photovoltaic device of claim 7, wherein the conductive coating is a non-continuous coating having a plurality of voids among the carbon nanotubes, and the transparent conductive layer fills the plurality of voids among the carbon nanotubes.

10. A photovoltaic device comprising:
a substrate;
a back contact layer disposed above the substrate;
an absorber layer disposed above the back contact layer;
a buffer layer disposed above the absorber layer, wherein both the absorber layer and the buffer layer are semiconductors;
a conductive coating comprising carbon nanotubes or graphene nanoplatelets disposed above the buffer layer; and
a transparent conductive oxide (TCO) layer disposed over the conductive coating.

11. The photovoltaic device of claim 10, wherein the conductive coating has a thickness in the range of from 0.5 nm to 500 nm.

12. The photovoltaic device of claim 10, wherein either the absorber layer or the buffer layer has a textured surface.

13. The photovoltaic device of claim 10, wherein the conductive coating comprises carbon nanotubes (CNT).

14. The photovoltaic device of claim 13, further comprising:
a scribe line extending into the buffer layer and the absorber layer, wherein the carbon nanotubes in the conductive coating over the buffer layer have an orientation substantially normal to the scribe line.

15. A method of fabricating a photovoltaic device, comprising
forming a back contact layer above a substrate;
forming an absorber layer for photon absorption above the back contact layer;
forming a buffer layer above the absorber layer;
depositing a conductive coating above the buffer layer; and
forming a transparent conductive layer over the conductive coating,
wherein the conductive coating comprises at least one type of nanomaterial having at least one dimension in the range of from 0.5 nm to 1000 nm.

16. The method of claim 15, wherein either the buffer layer or the absorber layer has a textured surface.

17. The method of claim 15, wherein the nanomaterial in the conductive coating comprises graphene nanoplatelets or carbon nanotubes (CNT).

18. The method of claim 15, wherein the conductive coating is formed by depositing the nanomaterial dispersed in a solution.

19. The method of claim 15, further comprising:
forming a scribe line extending into the buffer layer and the absorber layer.

20. The method of claim 19, wherein
depositing the conductive coating above the buffer layer is performed in a solution comprising carbon nanotubes (CNT) in an electric field; and
the conductive coating over the buffer layer comprises carbon nanotubes having an orientation substantially normal to the scribe line.
